(19) United States
(12) Patent Application Publication
(10) Pub. No.: US 2025/0157931 A1
(43) Pub. Date: May 15, 2025

(54) METHOD FOR PRODUCING A POWER SEMICONDUCTOR COMPONENT HAVING CONTACT METALLIZATION, EDGE PASSIVATION, AND POWER SEMICONDUCTOR COMPONENT

(71) Applicant: SEMIKRON DANFOSS ELEKTRONIK GMBH & CO. KG, NUREMERG (DE)

(72) Inventors: Bernhard KÖNIG, Fürth (DE); Klaus MÜMMLER, Erlangen (DE); Fryderyk KOZLOWSKI, Erlangen (DE); Wolfgang-Michael SCHULZ, Zimdorf (DE)

(73) Assignee: SEMIKRON DANFOSS ELEKTRONIK GMBH & CO. KG, NUREMBERG (DE)

(21) Appl. No.: 18/934,046

(22) Filed: Oct. 31, 2024

(30) Foreign Application Priority Data
Nov. 9, 2023 (DE) 10 2023 131 166.2

(51) Int. Cl. H01L 23/532; H01L 21/02; H01L 21/3205; H01L 29/06

(52) U.S. Cl. CPC H01L 23/53219; H01L 21/02118; H01L 21/02164; H01L 21/32051; H01L 23/5329; H10D 62/102

(57) ABSTRACT

A production method and a power semiconductor component having a semiconductor body have a first doping and a front side and a rear side, a central trough region in the semiconductor body on its front side, an edge structure of second doping surrounding the trough region in a ring shape on the front side and in an edge area of the power semiconductor component. The edge area directly adjoins the trough region, having a first silicon oxide layer in the edge area, wherein an outer section of the trough region is also covered, having an aluminium alloy, comprising aluminium and at least one further metal or metalloid; having a passivation, preferably a polyimide passivation on the outer section of the trough region and on the edge area.

### CROSS REFERENCE TO RELATED APPLICATIONS

This application relates to and claims priority to DE 10 2023 131 166.2 filed Nov. 9, 2023, the entire contents of which are incorporated herein fully by reference.

### FIGURE SELECTED FOR PUBLICATION

FIG. 1

### BACKGROUND OF THE INVENTION

### Field of the Invention

The invention describes a method for the production of and a power semiconductor component having a semiconductor body having a first doping and a front side and a rear side, having a central trough region in the semiconductor body on its front side, having an edge structure of second doping surrounding the trough region in a ring shape on the front side and in an edge area of the power semiconductor component, wherein the edge area directly adjoins the trough region, and having a contact metallization.

### Description of the Related Art

A semiconductor component having a semiconductor chip having a semiconductor component region, an aluminium-containing metal layer on the semiconductor component region, and having at least one additional metal layer on the aluminium-containing metal layer, which is harder than the aluminium-containing metal layer, is known from DE 10 2014 200 242 A1.

A consistent deficiency in such power semiconductor components is the robustness in relation to various environmental conditions, even when the power semiconductor components are installed in power semiconductor modules.

### Aspects and Objects of the Invention

With knowledge of these mentioned conditions, the invention is based on the object of presenting a method for producing a power semiconductor component and a power semiconductor component which is robust against environmental influences, in particular in offshore use.

This object is achieved according to the invention by a method for producing a power semiconductor component in a wafer composite comprising the following production steps:
a) providing a semiconductor body having a first doping and a front side and a rear side;
b) forming a central trough region in the semiconductor body having a second doping from the front side;
c) forming an edge structure of second doping, surrounding the trough region in a ring shape from the front side and in an edge area of the power semiconductor component, wherein the edge area directly adjoins the trough region;
d) forming a first silicon oxide layer in the edge area, wherein an outer section of the trough region is also overlapped;
e) applying an aluminium alloy, comprising aluminium and at least one further metal or metalloid;
f) applying a passivation, preferably a polyimide passivation, to the outer section of the trough region and to the edge area.

In this case, the production method was related to a power semiconductor component, although of course the entire production takes place in the wafer composite and the power semiconductor components are only provided individually thereafter by cutting the wafer.

It can be advantageous if steps b) and c) take place simultaneously and otherwise the steps take place in the specified sequence.

It can be preferred if the edge structure is formed as a plurality of field rings separate from one another. It can be preferred in this case if the first silicon oxide layer has a first window in the area of the field rings. Furthermore, it can be preferred if the first silicon oxide layer has a further section, which is arranged in an expanded outer section of the trough region.

Alternatively, it can be preferred if the edge structure is formed as a region of variable doping directly adjoining the trough region, wherein the doping concentration decreases outward.

In particular, it can be advantageous if the aluminium alloy is deposited simultaneously on the rear side. It can be preferred in this case if the aluminium alloy is deposited by means of sputtering.

It is particularly advantageous if the layer thickness of the aluminium alloy is 1 μm to 10 μm, preferably 2 μm to 8 μm, and particularly preferably 3 μm to 5 μm.

It is preferred if the aluminium alloy comprises at least one of the elements silicon, magnesium, or manganese.

It can be advantageous if, between steps d) and e), in a step d1), a polysilicon layer is deposited on the outer section of the trough region in the area of the first windows of the ring-shaped edge structure and on a section of the first silicon oxide layer surrounding one or both of these windows respectively. It can be preferred here if subsequent to step d1), in a step d2), a second silicon oxide layer is created on the outer section of the trough region and on the edge area. This second silicon oxide layer is advantageously made of tetraethyl orthosilicate (TEOS) and deposited in a chemical vapor deposition (CVD) method. Alternatively and by way of example, it can also be deposited as a so-called high temperature oxide by means of an LPCVD method.

Furthermore, it can be advantageous if following step d2), in step e), the aluminium alloy is also applied to first sections of the ring-shaped edge structure which have been made accessible.

In particular, it is advantageous if a nickel layer is deposited on the accessible surface of the aluminium alloy and a palladium layer is preferably deposited thereon, each preferably in a currentless or galvanic manner. It is preferred in this case if the layer thickness of the nickel layer is 0.5 μm to 10 μm, preferably 1 μm to 5 μm, and particularly preferably 2 μm to 4 μm and, if provided, the layer thickness of the palladium layer is 0.1 μm to 2 μm, preferably 0.5 μm to 1 μ, and particularly preferably 0.7 μm to 0.9 μm.

Furthermore, it is particularly advantageous if simultaneously with the respective layer on the front side, a nickel layer and, if provided, also a palladium layer are deposited on the rear side.

The above and below objects are furthermore achieved by a power semiconductor component having a semiconductor body having a first doping and a front side and a rear side, having a central trough region in the semiconductor body on its front side, having an edge structure of second doping surrounding the trough region in a ring shape on the front side and in an edge area of the power semiconductor component, wherein the edge area directly adjoins the trough region, having a first silicon oxide layer in the edge area, wherein an outer section of the trough region is also covered, having an aluminium alloy, comprising aluminium and at least one further metal or metalloid; having a passivation, preferably a polyimide passivation, on the outer section of the trough region and on the edge area.

It is obvious that the features mentioned above and hereinafter in the scope of the method can also be provided in the power semiconductor component.

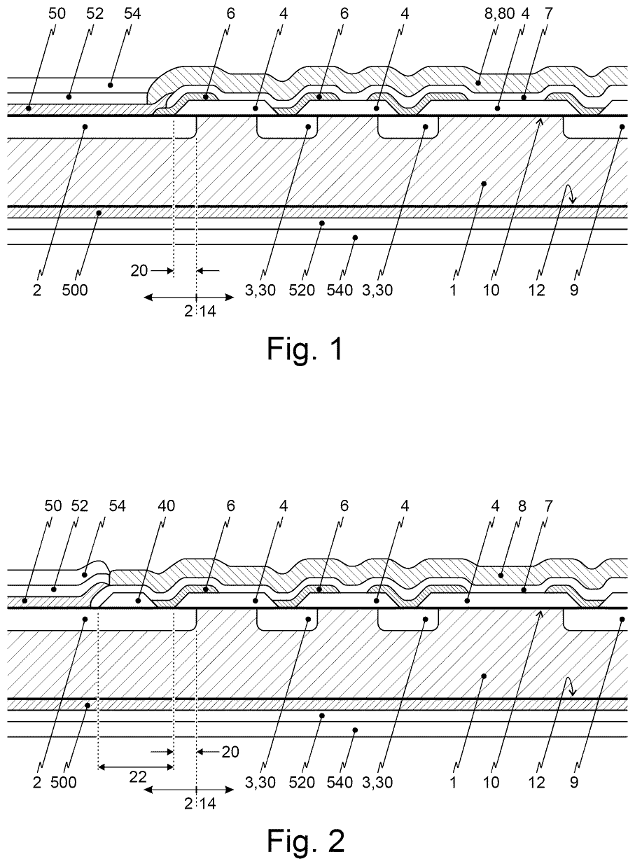

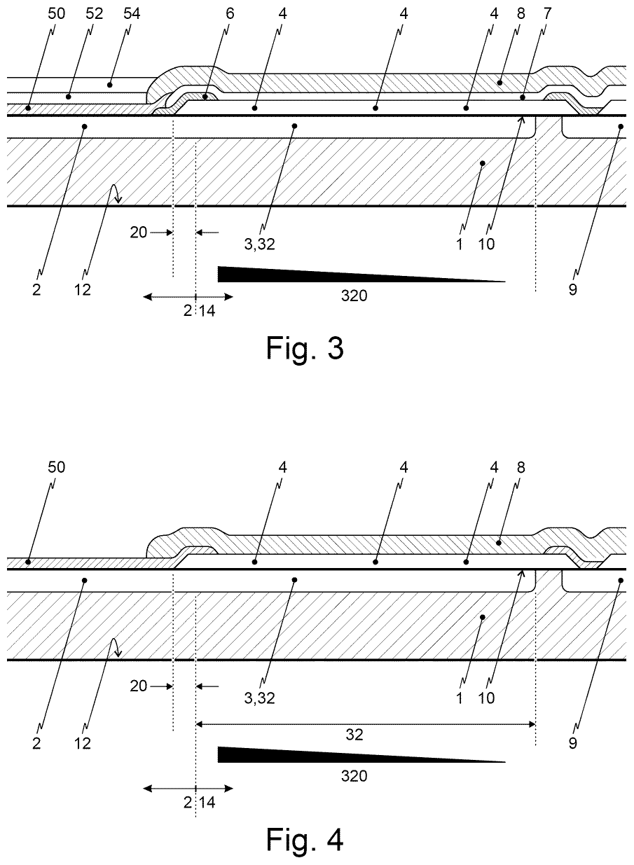

Further explanations of the invention, advantageous details, and features result from the following description of the exemplary embodiments of the invention schematically shown in FIGS. 1 to 4 or of respective parts thereof.

According to one alternative aspect and object of the present invention, there is presented A production method and a power semiconductor component having a semiconductor body have a first doping and a front side and a rear side, a central trough region in the semiconductor body on its front side, an edge structure of second doping surrounding the trough region in a ring shape on the front side and in an edge area of the power semiconductor component. The edge area directly adjoins the trough region, having a first silicon oxide layer in the edge area, wherein an outer section of the trough region is also covered, having an aluminium alloy, comprising aluminium and at least one further metal or metalloid; having a passivation, preferably a polyimide passivation on the outer section of the trough region and on the edge area.

The above and other aspects, features and advantages of the present invention will become apparent from the following description read in conjunction with the accompanying drawings, in which like reference numerals designate the same elements.

### BRIEF DESCRIPTION OF THE DRAWINGS

FIGS. 1 to 4 show four different designs of a power semiconductor component according to the invention produced by means of the method according to the invention, each in a representation which is not to scale. The design is on the basis of a single power semiconductor component in this case, although during the entire production of a power semiconductor component, it is present in the wafer composite and also all production steps relate to the wafer composite.

### DETAILED DESCRIPTION OF THE PREFERRED EMBODIMENTS

Reference will now be made in detail to embodiments of the invention. Wherever possible, same or similar reference numerals are used in the drawings and the description to refer to the same or like parts or steps. The drawings are in simplified form and are not to precise scale. The word ‘couple’ and similar terms do not necessarily denote direct and immediate connections, but also include connections through intermediate elements or devices. For purposes of convenience and clarity only, directional (up/down, etc.) or motional (forward/back, etc.) terms may be used with respect to the drawings. These and similar directional terms should not be construed to limit the scope in any manner. It will also be understood that other embodiments may be utilized without departing from the scope of the present invention, and that the detailed description is not to be taken in a limiting sense, and that elements may be differently positioned, or otherwise noted as in the appended claims without requirements of the written description being required thereto.

FIG. 1 shows a first design of a power semiconductor component according to the invention having a silicon semiconductor body 1 having a first n-doping here and having a front side 10 and a rear side 12, which forms the cathode of a diode here. A trough region 2 of a second p-doping here is formed on the front side 12. This trough region 2 forms, with its metallization described hereinafter, the anode of the diode and is arranged centrally on the front side 10 of the diode. The spatial design of the trough region 2 follows an outer contour, thus an edge of the diode, in a top view as is typical in the art. In the case of a round power semiconductor component, the trough region is therefore also formed round in a top view, while in square or rectangular power semiconductor components, it is also formed as such a square or rectangular region in a top view, however having rounded corners as is typical in the art.

The trough region 2 is surrounded in a ring shape by an edge area 14 of the power semiconductor component or the semiconductor body 1, which directly adjoins the trough region 2 and extends up to the outer edge of the power semiconductor component. An edge structure 3, which has two field rings 30 here without restriction of the generality, is formed in this edge area 14 as is typical in the art. A region 9 of third doping, here a region of high n-doping, is also arranged close to the edge of the power semiconductor component.

On the edge area 14 and into an outer section 20 of the trough region 2 directly adjoining the edge area 14, a first silicon oxide layer 4 is arranged, which has first windows centrally above the field rings 30. These first windows are therefore arranged circumferentially around the trough region 2 and spaced apart therefrom. The first windows only open the first silicon oxide 4 centrally and not at the edges of the field rings 30 when viewed laterally.

A polysilicon layer 6 is arranged in these windows, which in this exemplary embodiment also overlaps the silicon oxide layer 4 on the outside in the lateral direction in one section at the inner of the two field rings 30. The polysilicon layer 6 of the outer of the two field rings 30 overlaps the first silicon oxide layer 4 respectively at an inner and an outer section viewed in the lateral direction. The thickness of this polysilicon layer 6 is approximately 500 nm here.

The accessible sections of the first silicon oxide layer 4 and the polysilicon layers 6 are covered by a deposited second silicon oxide layer 7, which has a layer thickness of approximately 700 nm.

The accessible area of the trough region 2 is covered using a sputtered-on aluminium alloy 50 as a contact metallization having a thickness of 4 μm, which in addition to aluminium as the main component, also comprises silicon, magnesium, and manganese here. The preferred mass proportions are 0.7% to 1.3% silicon, 0.6% to 1.2% magnesium, and 0.4% to 1.0% manganese.

A particularly advantageous alternative aluminium alloy only comprises magnesium and manganese. The preferred mass proportions of this embodiment are 3.5% to 4.5% magnesium and 0.2% to 0.7% manganese.

The second silicon oxide layer 7 and also an edge area of the aluminium alloy 50 are covered with a passivation 8, a polyimide layer 80 here.

It is preferred and provided in this design if the accessible area of the aluminium alloy is covered using a 3 μm thick nickel layer and this is covered using a 0.8 μm thick palladium layer. These two layers are galvanically deposited here solely by way of example.

The rear side 12 of the power semiconductor component also has a layer sequence made up of a layer of an aluminium alloy 500, a nickel layer 520, and a palladium layer 540 having the same parameters as the corresponding layers of the front side 10.

FIG. 2 shows a second design of a power semiconductor component according to the invention. This differs from the first one in that an additional section 40 of the first silicon layer 4 is arranged on an expanded outer section 22 of the trough region 2, which adjoins the inside of the outer section 20 when viewed laterally and is only arranged there.

A polysilicon layer 4 is again arranged in a first window between this additional section 40 and the laterally following one. The second silicon oxide layer 7 is arranged on the still accessible surface of this additional section.

FIG. 3 shows a third design of a power semiconductor component according to the invention, having a silicon semiconductor body 1 having a first n-doping here and having a front side 10 and a rear side 12, which form the cathode of a diode here. A trough region 2 of a second p-doping here is again formed on the front side 1.

The trough region 2 is surrounded in a ring shape by an edge area 14 of the power semiconductor component, which directly adjoins the trough region 2 laterally and extends up to the outer edge of the power semiconductor component. An edge structure 3 is formed in this area as is typical in the art, which is formed here as a region 32 of variable doping. The doping, which becomes less outward, is indicated by the schematic representation of the doping concentration 320. This region 32 of variable doping directly adjoins the trough region 2 and is advantageously simultaneously produced therewith. A region 9 of third doping, a region of high n-doping here, is again arranged close to the edge of the power semiconductor component.

An uninterrupted first silicon oxide layer 4 is arranged on the edge area 14 and up into an outer section 20 of the trough region 2 directly adjoining the edge area 14.

A polysilicon layer 6 is arranged in each case on the inner and outer edges of the first silicon oxide layer 4 in a lateral view. The respective polysilicon layer 6 also overlaps the adjoining sections of the first silicon oxide layer 4.

The accessible sections of the first silicon oxide layer 4 and the polysilicon layers 6 are covered using a deposited second silicon oxide layer 7.

The accessible area of the trough region 2 is covered using a sputtered-on aluminium alloy 50 having a thickness of 4 μm, which, in addition to aluminium as the main component, also comprises silicon, magnesium, and manganese. This aluminium alloy also overlaps the sections of the polysilicon layer 6 and the second silicon oxide layer 7 in the outer section of the trough region and adjoining thereon.

The second silicon oxide layer 7 and also an edge area of the aluminium alloy 50 are covered using a passivation 8, a polyimide layer 80 here.

The accessible area of the aluminum alloy 50 is covered using a 3 μm thick nickel layer 52 and this is covered using a 0.8 μm thick palladium layer 54. These two layers are deposited in a currentless manner here solely by way of example.

FIG. 4 shows a fourth design of a power semiconductor component according to the invention. This differs from the third in that it does not have polysilicon layers.

Of course, it can be advantageous in the fourth design to arrange nickel and palladium layers, analogously to the first design. The rear sides of the third and fourth designs can also be formed analogously to the first design.

The above disclosure is sufficient to enable one of ordinary skill in the art to practice the invention, and provides a mode of practicing the invention. While this is a full and complete disclosure of the preferred embodiments of this invention, it does not limit the invention to the exact construction, dimensional relationships, and operations shown and described. Various modifications, alternative constructions, changes and equivalents will readily occur to those skilled in the art and may be employed, as suitable, without departing from the true spirit and scope of the invention. Such changes might involve alternative materials, components, structural arrangements, sizes, shapes, forms, functions, operational features or the like.

Also, the inventors intend that only those claims which use the specific and exact phrase “means for” are intended to be interpreted under 35 USC 112. The structure, device, and arrangement herein is noted and well supported in the entire disclosure. Moreover, no limitations from the specification are intended to be read into any claims, unless those limitations are expressly included in the claims.

Having described at least one of the preferred embodiments of the present invention with reference to the accompanying drawings, it will be apparent to those skills that the invention is not limited to those precise embodiments, and that various modifications and variations can be made in the presently disclosed system without departing from the scope or spirit of the invention. Thus, it is intended that the present disclosure covers modifications and variations of this disclosure provided they come within the scope of the appended claims and their equivalents.

Although only a few embodiments have been disclosed in detail above, other embodiments are possible and the inventors intend these to be encompassed within this specification. The specification describes certain technological solutions to solve the technical problems that are described expressly and inherently in this application. This disclosure describes embodiments, and the claims are intended to cover any modification or alternative or generalization of these embodiments which might be predictable to a person having ordinary skill in the art.

Therefore, the above description and illustrations should not be construed as limiting the scope of the invention, which is defined by the claims set out herein.

What is claimed is:

1. A method for producing a power semiconductor component in a wafer composite, comprising the following production steps:
a) providing a semiconductor body (1) having a first doping and a front side (10) and a rear side (12);
b) forming a central trough region (2) in the semiconductor body (1) having a second doping from the front side (10);
c) forming an edge structure (3) of second doping, surrounding the central trough region (2) in a ring shape, from the front side (10) and in an edge area (14) of the power semiconductor component, wherein the edge area (14) directly adjoins the trough region (2);
d) forming a first silicon oxide layer (4) in the edge area (14), wherein an outer section (20) of the central rough region (2) is also overlapped;
e) applying an aluminium alloy (50), comprising aluminium and at least one further metal or metalloid; and
f) applying a passivation (8), preferably a polyimide passivation (80), to the outer section (20) of the trough region (2) and to the edge area (14).

2. The method, according to claim 1, wherein:
steps b) and c) take place simultaneously.

3. The method, according to claim 2, wherein:
the edge structure (3) is formed as a plurality of field rings (30) separate from one another.

4. The method, according to claim 2, wherein:
the edge structure (3) is formed as a region of variable doping (32) directly adjoining the central trough region, wherein the doping concentration (320) decreases outward.

5. The method, according to claim 3, wherein:
the first silicon oxide layer (4) has first windows in the area of the field rings (30).

6. The method, according to claim 4, wherein:
the first silicon oxide layer (4) has a further section (40), which is arranged in an expanded outer section (22) of the central trough region (2).

7. The method, according to claim 1, wherein:
the aluminium alloy is deposited simultaneously on the rear side (12).

8. The method, according to claim 7, wherein:
the aluminium alloy (50) is deposited by a step of sputtering.

9. The method, according to claim 8, wherein:
the layer thickness of the aluminium alloy (50) is 1 μm to 10 μm.

10. The method, according to claim 8, wherein:
the aluminium alloy (50) comprises at least one of the elements silicon, magnesium, or manganese.

11. The method, according to claim 1, wherein:
between steps d) and e);
in a step d1), a polysilicon layer (6) is deposited on the outer section (20) of the trough region (2) in the area of the windows of the ring-shaped edge structure (3) and on a section of the first silicon oxide layer (4) surrounding one or both of these windows respectively.

12. The method, according to claim 11, wherein:
subsequent to step d1), in a step d2);
a second silicon oxide layer (7) is created on the outer section (20) of the trough region (2) and on the edge area (14).

13. The method, according to claim 12, wherein:
subsequent to step d2), in step e);
the aluminium alloy is also applied to central sections of the ring-shaped edge structure (3) made accessible by means of second windows.

14. The method, according to claim 13, wherein:
a nickel layer (52) is deposited on the accessible surface of the aluminium alloy (50) and a palladium layer (54) is deposited thereon, each in a currentless or galvanic manner.

15. The method according to claim 14, wherein:
the layer thickness of the nickel layer is 0.5 μm to 10 μm; and
if provided, the layer thickness of the palladium layer is 0.1 μm to 2 μm.

16. The method according to claim 15, wherein:
simultaneously with the respective layer on the front side (10), a nickel layer (520) and also a palladium layer (540) are deposited on the rear side (12).

17. A power semiconductor component, formed according to the method of claim 1, comprising:
a semiconductor body (1) having a first doping and a front side (10) and a rear side (12), having a central trough region (2) in the semiconductor body on its front side (10);
an edge structure (3) of a second doping, surrounding the central trough region (2) in a ring shape, on the front side (10) and in an edge area (14) of the power semiconductor component;
wherein the edge area (14) directly adjoins the central trough region (2), having a first silicon oxide layer (4) in the edge area (14);
wherein an outer section (20) of the central trough region (2) is also covered with an aluminium alloy (50); and
the aluminium alloy (50) further comprises:
at least one further metal or metalloid; having one of a passivation (8) and a polyimide passivation (80) on one of the outer section (20) of the central trough region (2) and on the edge area (14).
